(19) United States
(12) Patent Application Publication
(10) Pub. No.: US 2006/0255608 A1
(43) Pub. Date: Nov. 16, 2006

(54) Arrangement of groups of electronic components in a vehicle cockpit

(75) Inventors: Jurgen Dreyer, Schaafheim-Mosbach (DE); Winfried Moll, Laubach (DE); Heiko Schnieders, Schaafheim (DE); Levente Szoke, Dieburg (DE)

Correspondence Address: MORRISON & FOERSTER LLP, 1650 TYSONS BOULEVARD, SUITE 300, MCLEAN, VA, 22102, US

(73) Assignee: Siemens Aktiengesellschaft, Munchen (DE)

(21) Appl. No.: 11/408,237

(22) Filed: Apr. 21, 2006

(30) Foreign Application Priority Data
Apr. 25, 2005 (DE) 10 2005 019 117.7

(51) Int. Cl. B62D 25/14

(52) U.S. Cl. 296/24.34; 280/728.2; 296/37.12

(57) ABSTRACT

The invention relates to an arrangement of groups of electronic components in the cockpit of a motor vehicle having a first group of electronic components for controlling a first vehicle function mounted on a first printed circuit board (9). According to the invention the printed circuit board (9) is fixed directly onto a support and/or a front panel (1) of the cockpit.

The invention relates to an arrangement of groups of electronic components in the cockpit of a motor vehicle having a first group of electronic components for controlling a first vehicle function mounted on a first printed circuit board.

Different groups of electronic components required for controlling various vehicle functions are arranged in today's motor vehicle cockpits. In addition to controlling basic function elements of the vehicle such as the exterior lighting and the window wipers, and in addition to the visual display of vehicle states, the electronics housed in today's cockpits are also used to control a car radio and/or entertainment equipment, an air conditioning control system and/or navigation equipment. These groups of electronic components are each arranged in stand-alone enclosures, as described in German patent DE 32 26 972 A1 for example, or as also known from the DIN slot enclosure designs.

The object of the present invention is to improve the arrangement of groups of electronic components cited in the introduction, in particular with regard to the space required.

This object is achieved by an arrangement as claimed in claim 1.

Fixing the first printed circuit board directly onto base elements of the cockpit, i.e. onto a support and/or a front panel, dispenses with the enclosure for the first group of electronic components. This saves the empty space that always exists in enclosures, i.e. additional printed circuit boards having additional groups of electronic components can be arranged in the cockpit with higher packing density. Fixing the printed circuit board/boards, which are distinctly smaller than an enclosure, directly to cockpit elements provides the additional advantage that more intelligent use can be made of the available space. There is no longer the need to provide slots or larger areas of space for the enclosure arrangement. Instead, small recesses inside the cockpit can even be used for mounting the printed circuit boards.

In a preferred embodiment, the first printed circuit board is not only used for a first group of electronic components, but a second group of electronic components for controlling a second vehicle function is also mounted on the first printed circuit board. This therefore also dispenses with another enclosure that would normally be provided for the second group of electronic components. Integrating a plurality of vehicle functions, for example the air conditioning control system and the car radio function, on one and the same printed circuit board, additionally creates the advantage that the same components present in both groups of components only need to be provided once. Thus, for example, the power supply can be shared and it suffices to provide just one processing unit and to implement both vehicle functions in it. This not only saves space but also costs.

Preferably, the first printed circuit board is fixed onto a rear side, facing away from the passenger compartment, of the front panel. This simplifies assembly because the printed circuit board can be pre-fitted on the back of the front panel before it is inserted in the cockpit. Front panels also have the advantage that they generally have larger, approximately flat surfaces. This suits the rigid planar form of printed circuit boards, which can be arranged parallel to these surfaces and fixed to them. In addition, ribs, webs or receptacles for screws or clips required for fixing the printed circuit boards can be molded onto the front panels, which are usually produced in the injection molding process, when they are made, i.e. no additional process step is required.

In a development, if a plurality of printed circuit boards are fixed to the rear side of the front panel, and the front panel is curved, the printed circuit boards are designed in size so that they can be arranged at a minimum distance from the rear side of the front panel. The printed circuit boards are thus arranged along the curvature side-by-side or overlapping. It is also conceivable, in order to make use of curved areas having a comparatively small radius, to-split the first printed circuit board into two printed circuit boards, which are then placed inside the curvature. Thus dispensing with the enclosure allows greater overall scope for utilizing the space in the cockpit.

If printed circuit boards are not fixed directly flat on the rear side of front panels, it is provided in a further embodiment that grooves are made or mounted on the support and/or front panel, into which the printed circuit boards are slotted using at least one of their edge areas.

In addition to the function of providing mechanical rigidity, enclosures also often perform the function of shielding the groups of electronic components from electromagnetic radiation. Cockpit elements can take on this function when they are provided at least partially with a conductive coating.

In a particular embodiment of the invention, the rear side of the front panel of a center console of a motor vehicle is used for mounting the printed circuit boards.

The invention is described in more detail below with reference to an exemplary embodiment and the drawing, in which

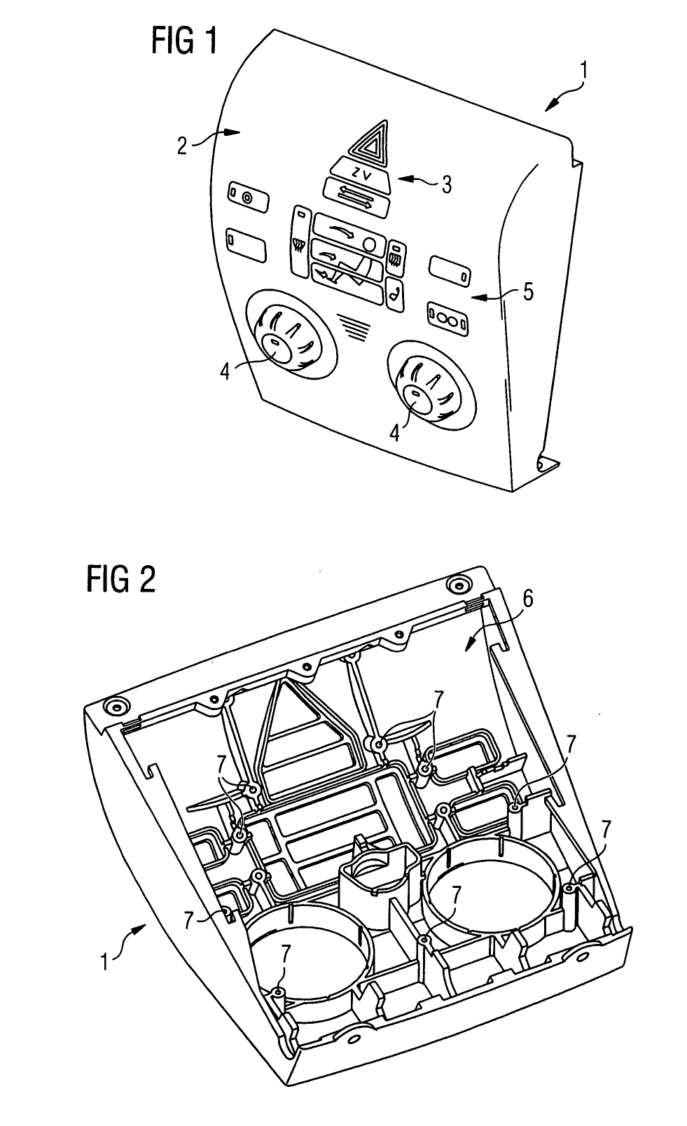

FIG. 1 shows the front side of a front panel of a center console;

FIG. 2 shows the rear side of the front panel of FIG. 1;

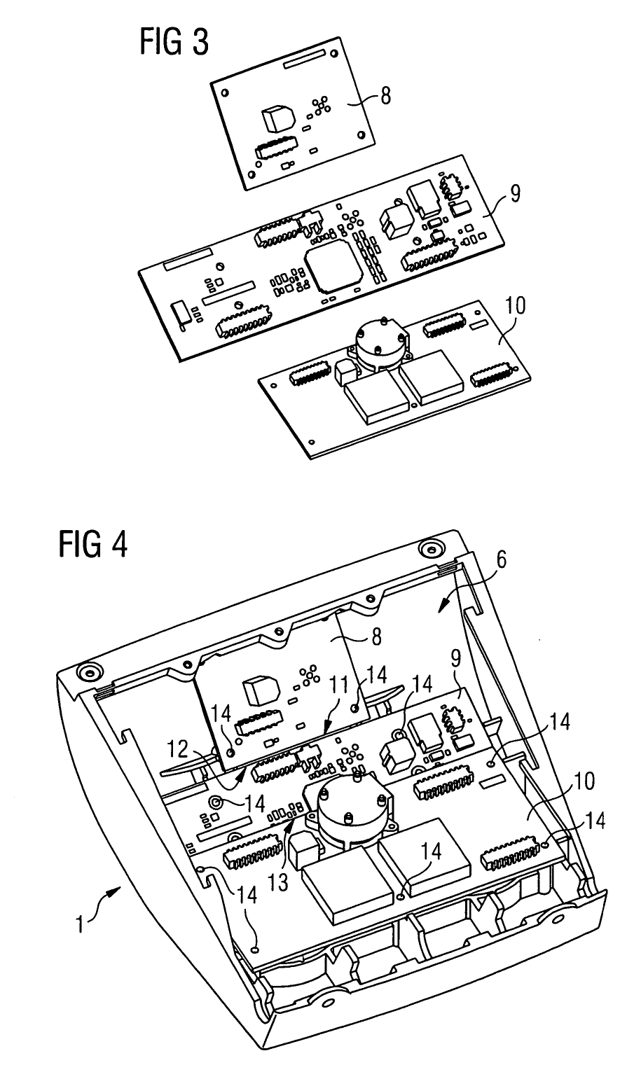

FIG. 3 shows three printed circuit boards having four groups of electronic components;

FIG. 4 shows the printed circuit boards of FIG. 3 fixed to the rear side shown in FIG. 2.

FIG. 1 shows the front side 2 of a front panel 1 of a center console of a motor vehicle. Two rotary control knobs 4, a top control panel 3 comprising control buttons of various size and shape, and a central control panel 5 comprising rectangular control buttons are shown. FIG. 2 shows the rear side 6 belonging to the front panel 1. The receptacles 7 provided for screws and molded directly onto the front panel 1 are clearly visible.

The printed circuit boards 8, 9 and 10 shown in FIG. 3 are provided for fixing on the rear side 5 of the front panel 1. Since the front panel 1 and hence also the rear side 7 is curved outwards towards the passenger compartment of the motor vehicle, the printed circuit boards 8, 9 and 10 are designed to have a different height and width so that they can fit as well as possible into the curvature. The printed circuit board 8 carries a first group of electronic components, which in addition to detecting the operation of the control buttons of the top control panel 3, is used for controlling the exterior lights of the motor vehicle, for example. A second group of electronic components accommodated on the printed circuit board 9 monitors the operation of the control buttons of the central control panel 5 and controls the air conditioning and ventilation system of the vehicle, while a third group of electronic components, also arranged on the printed circuit board 9, controls all the car radio functions. A fourth group of electronic components on the printed circuit board 10 reads the operations of the two rotary control knobs 4 and controls functions in the vehicle interior such as seat adjustment and interior lighting.

FIG. 4 shows the rear side 6 of the front panel 1 and the printed circuit boards 8, 9 and 10 in the assembled state. Screws (not shown) are screwed into the holes 14, thereby engaging in the receptacles 7, whereby the printed circuit boards 8, 9 and 10 are fixed to the rear side 6 of the front panel 1. The edge areas 11 and 12 of the printed circuit boards 8 and 9 abut each other, while the edge area 13 of the printed circuit board 10 slightly overlaps the printed circuit board 9, the printed circuit board 10 being at a somewhat larger distance from the rear side 6. The printed circuit board arrangement has been fitted to the curvature of the front panel 1 with optimum use of the available space by means of the slight overlap. Each of the printed circuit boards 8, 9 and 10 is aligned substantially parallel to the rear side 6.

1. An arrangement of groups of electronic components in the cockpit of a motor vehicle having a first group of electronic components for controlling a first vehicle function mounted on a first printed circuit board (9), characterized in that the printed circuit board (9) is fixed directly onto a support and/or a front panel (1) of the cockpit.

2. The arrangement as claimed in claim 1, characterized in that a second group of electronic components for controlling a second vehicle function is also mounted on the first printed circuit board (9).

3. The arrangement as claimed in one of the preceding claims, characterized in that the first printed circuit board (9) is fixed onto a rear side (6), facing away from the passenger compartment, of the front panel (1).

4. The arrangement as claimed in claim 3, characterized in that the rear side (6) of the front panel (1) is curved, and that the first printed circuit board (9) and a second printed circuit board (8, 10) having an additional group of electronic components are fixed along the curvature, the printed circuit boards being aligned substantially parallel to the rear side.

5. The arrangement as claimed in one of the preceding claims, characterized in that the first printed circuit board (9) is fixed by screws or clips.

6. The arrangement as claimed in one of the preceding claims, characterized in that the-first printed circuit board (9) is inserted by at least one side edge area in at least one groove made or mounted on the support and/or front panel of the cockpit.

7. The arrangement as claimed in one of the preceding claims, characterized in that the support and/or front panel is provided at least partially with a conductive coating for electromagnetic shielding of the first group of electronic components.

8. The arrangement as claimed in one of the preceding claims, characterized in that the front panel (1) covers components of a central console.
